(19) United States
(12) Patent Application Publication
(10) Pub. No.: US 2025/0316458 A1
(43) Pub. Date: Oct. 9, 2025

(54) APPARATUS FOR PROCESSING A SUBSTRATE

(71) Applicant: SAMSUNG ELECTRONICS CO., LTD., SUWON-SI (KR)

(72) Inventors: Jimo LEE, Suwon-si (KR); Kyung-Sun KIM, Suwon-si (KR); Nam Kyun KIM, Suwon-si (KR); Donghyeon NA, Suwon-si (KR); Yoonbum NAM, Suwon-si (KR); Seungbo SHIM, Suwon-si (KR); Kuihyun YOON, Suwon-si (KR); Juneeok LEEM, Suwon-si (KR); Taeil CHO, Suwon-si (KR); Minyoung HUR, Suwon-si (KR)

(21) Appl. No.: 18/937,222

(22) Filed: Nov. 5, 2024

(30) Foreign Application Priority Data
Apr. 5, 2024 (KR) 10-2024-0046902

(51) Int. Cl. H01J 37/32; H01L 21/687

(52) U.S. Cl. CPC H01J 37/32642; H01J 37/32715; H01L 21/68785

(57) ABSTRACT

An apparatus of processing a substrate, the apparatus including: a substrate supporting unit configured to support the substrate; a control assembly disposed along an outer edge of the substrate supporting unit, the control assembly including a plurality of blades, wherein the plurality of blades are configured to combine and form a control ring that surrounds the outer edge of the substrate supporting unit; and a plasma generating unit disposed to face the substrate supporting unit, wherein the control ring has an inner diameter that is changeable during an operation of the plasma generating unit.

### CROSS-REFERENCE TO RELATED APPLICATION(S)

This application claims priority under 35 U.S.C. § 119 to Korean Patent Application No. 10-2024-0046902, filed on Apr. 5, 2024, in the Korean Intellectual Property Office, the disclosure of which is incorporated by reference herein in its entirety.

### 1. Technical Field

Example embodiments of the present disclosure relate to an apparatus for processing a substrate.

### 2. Description of the Related Art

The process for manufacturing a semiconductor device includes several plasma-based operations, including plasma induction, deposition, etching, and cleaning. With the ongoing miniaturization and increasing complexity of semiconductor devices, even minor errors in the plasma process can significantly impact product quality and yield.

Factors influencing yield during semiconductor manufacturing, particularly in the plasma processes, include precise control of the plasma distribution area. For example, in plasma etching, accurately controlling the plasma distribution area at the edge of a semiconductor wafer (referred to as a substrate) is critical for determining overall yield.

As a result, various studies are underway to improve the reliability of plasma equipment by optimizing control of the plasma distribution area.

### SUMMARY

An example embodiment of the present disclosure provides an apparatus for substrate processing, configured to control the plasma distribution area during plasma processes in semiconductor device manufacturing.

An example embodiment of the present disclosure provides an apparatus of processing a substrate, the apparatus including: a substrate supporting unit configured to support the substrate; a control assembly disposed along an outer edge of the substrate supporting unit, the control assembly including a plurality of blades, wherein the plurality of blades are configured to combine and form a control ring that surrounds the outer edge of the substrate supporting unit; and a plasma generating unit disposed to face the substrate supporting unit, wherein the control ring has an inner diameter that is changeable during an operation of the plasma generating unit.

An example embodiment of the present disclosure provides an apparatus of processing a substrate, the apparatus including: a substrate supporting unit configured to support the substrate; a control assembly disposed along an outer edge of the substrate supporting unit, the control assembly including a plurality of blades having an arc-shape extending along a circumferential direction of the substrate, wherein the plurality of blades are configured to form a control ring that surrounds the outer edge of the substrate supporting unit; and a plasma generating unit disposed to face the substrate supporting unit, wherein a distance between innermost points of the plurality of blades, closest to the substrate, and the substrate is variable.

An example embodiment of the present disclosure provides an apparatus of processing a substrate, the apparatus including: a substrate supporting unit configured to support the substrate; a control assembly disposed along an outer edge of the substrate supporting unit, the control assembly including a plurality of blades having an arc-shape extending along a circumferential direction of the substrate, wherein the blades combined to form a control ring that surrounds the outer edge of the substrate supporting unit; and a plasma generating unit disposed to face the substrate supporting unit, wherein the control assembly further includes: a base part, having a ring shape, that surrounds the outer edge of the substrate supporting unit; a rotation part, concentric with the base part, disposed over the base part, configured to rotate along a circumferential direction of the base part, and operate the plurality of blades; and a cover part, having a ring shape, disposed to cover the plurality of blades, and having an inner diameter that is equal to or smaller than an inner diameter of the control ring, wherein the rotation part includes a plurality of first connection parts disposed along the circumferential direction, each first connection part having an oval shape with its long axis oriented along a direction of a diameter of the substrate, wherein the cover part includes a plurality of first fixing parts in the form of grooves arranged along the circumferential direction, wherein each of the plurality of blades include: a second connection part at one end, protruding toward the rotation part, and inserted into a corresponding first connection part; and a second fixing part at the opposite end, protruding toward the cover part, and inserted into a corresponding first fixing part, wherein the inner diameter of the control ring changes with the rotation of the rotation part, wherein the plurality of second connection parts move within the plurality of first connection parts when the rotation part rotates, wherein locations of the plurality of first fixing parts and the plurality of second fixing parts are fixed when the rotation part rotates, and wherein the plurality of blades overlap the substrate in the direction of the diameter of the substrate.

According to example embodiments of the present disclosure, the horizontal direction of the plasma distribution area can be controlled in real time through the hardware structure of a control assembly. This control assembly enables real time adjustments to the plasma distribution area during the plasma process in semiconductor device manufacturing, enhancing productivity by preventing process interruptions. Additionally, the control assembly allows for the distribution of plasma to be precisely controlled across both the center and edge of the substrate. The control assembly also provides the capability to control the plasma distribution area linearly and symmetrically along the diameter of the substrate, ensuring active and precise control of the plasma distribution area during the plasma process.

### BRIEF DESCRIPTION OF THE DRAWINGS

These and/or other features of the present disclosure will become apparent and more readily appreciated from the following description of example embodiments thereof, taken in conjunction with the accompanying drawings of which:

FIG. 1 is a diagram schematically showing a substrate processing apparatus according to an example embodiment;

FIG. 2 is an exploded perspective view of a control assembly included in a substrate processing apparatus and a partial cross-sectional view of other elements according to an example embodiment;

FIG. 3 is a combined perspective view of a control assembly included in a substrate processing apparatus and a partial cross-sectional view of other elements according to an example embodiment;

FIG. 4 is a diagram for explaining a control ring of a substrate processing apparatus according to an example embodiment;

FIGS. 5 and 6 are diagrams of a control assembly included in a substrate processing apparatus according to an example embodiment;

FIG. 7 is a diagram of a base part of a control assembly included in a substrate processing apparatus according to an example embodiment;

FIG. 8 is a diagram of a rotation part of a control assembly included in a substrate processing apparatus according to an example embodiment;

FIG. 9 is a diagram of a cover part of a control assembly included in a substrate processing apparatus according to an example embodiment;

FIG. 10 is a diagram of a blade of a control assembly included in a substrate processing apparatus according to an example embodiment;

FIGS. 11A, 11B and 11C are diagrams schematically showing a state in which blades continuously change according to a rotation of a rotation part; and

FIGS. 12, 13, 14, 15 and 16 are diagrams illustrating movements of a plurality of blades according to a rotation of a rotation part of a control assembly included in a substrate processing apparatus according to some example embodiments.

### DETAILED DESCRIPTION OF THE EMBODIMENTS

The same reference numerals or symbols used in the attached drawings may denote parts or components that perform substantially the same function. For ease of description and understanding, different embodiments may use the same reference numerals or symbols. However, components or elements identified by the same reference numeral in multiple drawings do not necessarily represent a single embodiment.

In the following description, singular terms are intended to encompass their plural counterparts unless the context clearly dictates otherwise. It will be understood that when an element (for example, a first element) is described as being “(operatively or communicatively) coupled with/to” or “connected to” another element (for example, a second element), the coupling or connection may be direct, or there may be an intervening element (for example, a third element) between the two. The terms “have,” “may have,” “include,” and “may include” as used herein indicate the presence of corresponding features (such as elements, numerical values, functions, operations, or parts), and do not preclude the presence of additional features.

Further, in the following description, terms such as “upper side,” “top,” “lower side,” “bottom,” “side,” “front” and “back” are used based on the direction shown in the drawing. If the direction of the object changes, these terms may be expressed differently.

Further, in the specification and claims, terms like “first,” “second,” and other ordinal numbers may be used to distinguish between components or elements. These ordinal numbers are used to distinguish identical or similar components from each other and should not be interpreted as imposing any limitations. For example, components or elements associated with these ordinal numbers should not be interpreted as having a specific order of use or arrangement based on the number. If necessary, each ordinal number may be used interchangeably.

Hereinafter, example embodiments of the present disclosure will be described in detail with reference to the attached drawings. However, the scope of the present disclosure is not limited to these example embodiments. For example, a person skilled in the art who understands the principles of the present disclosure may propose additional embodiments, involving modifications, changes, or deletions of components or elements, that still fall within the scope of the present disclosure. Such embodiments are intended to be included within the scope of this disclosure. The shapes and sizes of elements in the drawings may be exaggerated for clarity.

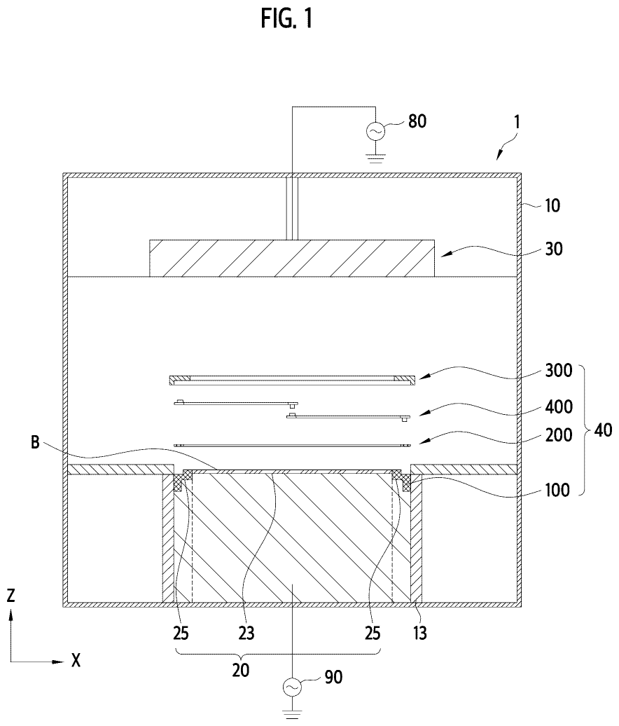

FIG. 1 is a diagram schematically showing a substrate processing apparatus 1 according to an example embodiment.

Referring to FIG. 1, the substrate processing apparatus 1 may include a chamber 10, a substrate supporting unit 20, a control assembly 40, and a plasma generating unit 30.

The chamber 10 according to an example embodiment may be configured to provide a processing space therein. The chamber 10 may be configured to ensure effective sealing. The chamber 10 may include a passage for introducing a substrate on a side wall. In other words, the chamber 10 may include a sidewall passage for substrate introduction. The chamber 10 may be configured to remove debris generated during substrate processing.

In some example embodiments, the outer structure of the chamber 10 may be cylindrical, oval, or polygonal in shape. The chamber 10 is generally made of a metal material, and is kept electrically grounded during the plasma process to block external noise.

In some example embodiments, a liner may be provided inside the chamber 10. The liner may protect the chamber 10 and cover metal structures within the chamber 10 to prevent metal contamination caused by internal arcing. The liner may be formed of a metal material such as aluminum or a ceramic material. Further, the liner may be formed of a material film resistant to plasma. Here, the material film that is resistant to plasma may be, for example, an yttrium oxide (Y₂O₃) film. However, the material film resistant to plasma is not limited to the yttrium oxide film.

In some example embodiments, a shower head may be placed within the chamber 10. The shower head may include a plurality of holes. The shower head may spray process gas through the plurality of holes to generate plasma.

In some example embodiments, the chamber 10 may include a partition wall 13. The partition wall 13 may partition the inner surface of the chamber 10 and the substrate supporting unit 20. The partition wall 13 may protect the inside of the chamber 10 from debris generated during processing and residual gases. A base part 100 of the control assembly 40 described above may be provided between the partition wall 13 and the substrate supporting unit 20. This structure allows the base part 100 of the control assembly 40 to be firmly placed, enhancing the precision of its operation.

In some example embodiments, the substrate processing apparatus 1 may be a chamber for processing substrate B using plasma and/or radicals. The plasma process may be performed on the substrate B within the substrate processing apparatus 1. For example, an etching process using plasma may be performed on the substrate B, but the present disclosure is not limited thereto. In another example embodiment, a deposition process, an ashing process and a cleaning process may be performed within the substrate processing apparatus 1.

In the present disclosure, the term “substrate” may refer to the substrate itself, or a laminated structure including the substrate and a predetermined layer or a film formed on its surface. Further, “surface of the substrate” may refer to the exposed surface of the substrate itself, or the exposed surface of a predetermined layer or a film formed on the substrate. For example, the substrate may be a wafer, or the substrate may refer to a wafer along with at least one material film on the wafer. The material film may be an insulating film or a conductive film formed on a wafer through various methods such as deposition, coating and plating. For example, the insulating film may include an oxide film, a nitride film or an oxynitride film, and the conductive film may include a metal film or a polysilicon film. The material film may be a single film or a multi-layer film formed on a wafer. Further, the material film may be formed on a wafer with a predetermined pattern.

According to some example embodiments, the substrate supporting unit 20 may be configured to allow the substrate B to be seated. The substrate supporting unit 20 may include a first part 23 and a second part 25.

According to some example embodiments, the first part 23 may be placed inside the second part 25. For example, the first part 23 may be located between left and right sides of the second part 25 along the X-axis direction as shown in FIG. 1. The first part 23 may accommodate the substrate B. In other words, the substrate B may be disposed on the first part 23 and may overlap the first part 23 in the Y-axis direction. The second part 25 may surround the first part 23. The second part 25 may support the base part 100, which will be described later. For example, the base part 100 may be provided on the second part 25. The top surface of the second part 25 may be lower than the top surface of the first part 23. The second part 25 may be provided with a step so that the base part 100, which will be described later, may be stably seated.

According to some example embodiments, the substrate supporting unit 20 may support the substrate B. The substrate B may be seated on the top surface of the substrate supporting unit 20. The substrate supporting unit 20 may be an electrostatic chuck. The electrostatic chuck may include electrodes for chucking and dechucking the substrate B. For example, the electrode of the electrostatic chuck is connected to a second power 90 (or second power source) and may receive radio frequency (RF) power from the second power 90. The chuck support, which holds the electrostatic chuck in place, may be formed from a metal such as aluminum or a ceramic insulator such as alumina. A heating member such as a heater is placed inside the chuck support, and heat may be transferred from the heater to the electrostatic chuck or the substrate B. Further, a power supply wire connected to the electrode of the electrostatic chuck may be placed on the chuck support. However, the substrate supporting unit 20 is not limited thereto. For another example, the substrate supporting unit 20 may be equipped with a vacuum chuck to support the substrate B using vacuum pressure, or it may be configured to mechanically support the substrate B.

In some example embodiments, the plasma generating unit 30 may be arranged to face the substrate supporting unit 20. The plasma generating unit 30 may be located on top of the substrate supporting unit 20. The plasma generating unit 30 may generate plasma and concentrate the plasma on the top surface of the substrate B seated on the substrate supporting unit 20. The plasma generating unit 30 may be connected to a first power 80 (or first power source) for plasma generation. For example, the plasma generating unit 30 may receive RF power from the first power 80 and excite the source gas supplied into the chamber 10 to form plasma.

In some example embodiments, the control assembly 40 may be arranged along the outer edge of the substrate supporting unit 20. The control assembly 40 may include a plurality of blades 400. The control assembly 40 may form a control ring surrounding the outer edge of the substrate supporting unit 20 by combining the plurality of blades 400. The inner diameter of the control ring formed by the plurality of blades 400 may be changeable during the operation of the plasma generating unit 30.

In some example embodiments, the control assembly 40 may be configured to adjust the plasma distribution area, ensuring that the plasma generated by the plasma generating unit 30 is evenly distributed across the substrate B on the same or parallel plane as the substrate B seated on the substrate supporting unit 20.

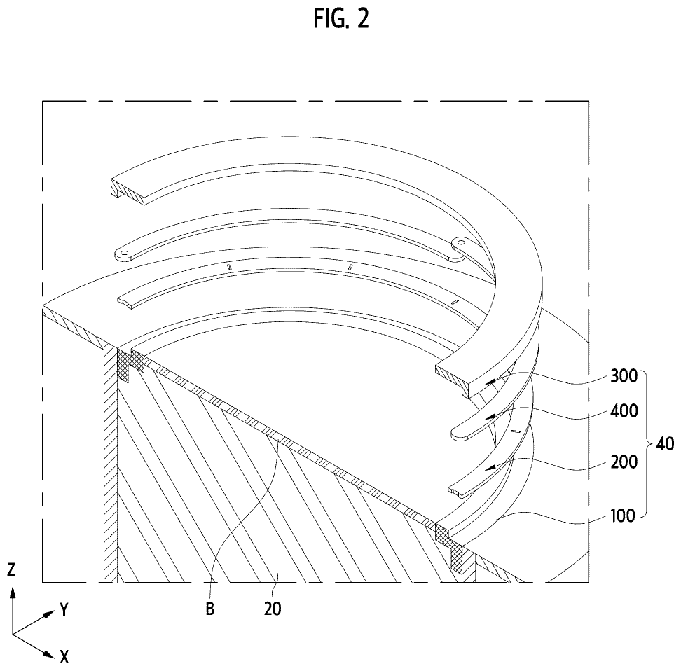

Hereinafter, the control assembly 40 will be described in more detail with reference to FIGS. 2 to 4.

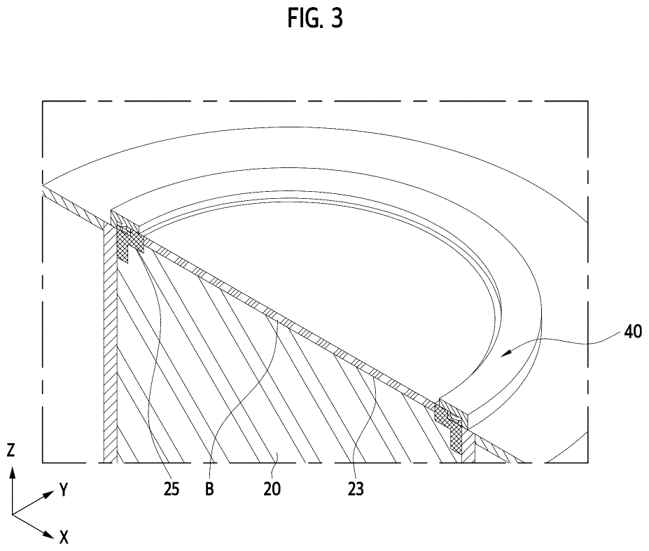

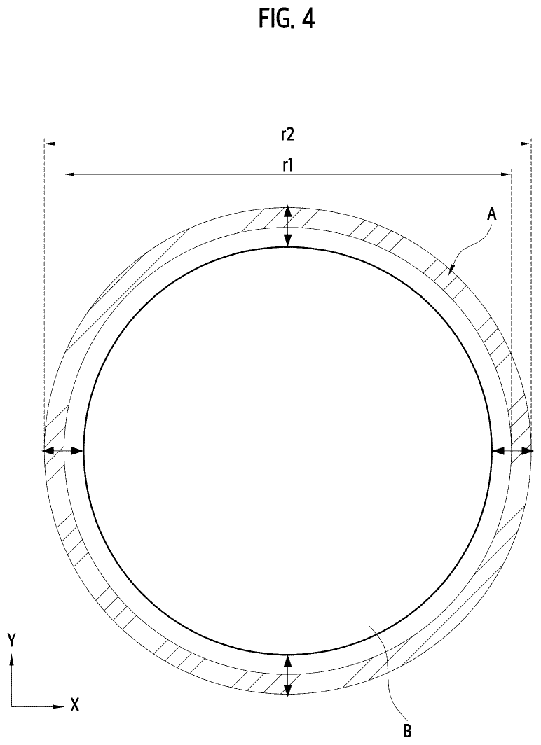

FIG. 2 illustrates an exploded perspective view of the control assembly 40 and a partial cross-sectional view of other elements included in the substrate processing apparatus 1 according to some example embodiments. FIG. 3 is a combined perspective view of the control assembly 40 and a partial cross-sectional view of other elements included in the substrate processing apparatus 1 according to some example embodiments. FIG. 4 is a diagram for explaining control ring A of the substrate processing apparatus 1 according to some example embodiments.

Referring to FIGS. 2 to 4, the substrate B settled on the substrate supporting unit 20 may be circular. The center of the substrate B may coincide with the center of the control ring A.

According to some example embodiments, the control assembly 40 may be configured to gradually increase or decrease the inner diameter of the control ring A.

In other words, referring to FIG. 4, the control assembly 40 may control the movement of the control ring A on the XY plane, which is either the same as or parallel to the plane of the substrate B. The control assembly 40 may adjust the control ring A along the horizontal direction on this same or parallel plane.

According to some example embodiments, outer diameter r2 of the control ring A may be constant. Inner diameter r1 of the control ring A may be at least equal to or larger than the diameter of the substrate B. Therefore, even if the inner diameter r1 of the control ring A is at its minimum, the substrate B may still be shielded by the control ring A or prevented from contacting the control ring A.

With the configuration of the present disclosure, the inner diameter r1 of the control ring A may be adjusted in real time through the hardware structure of the control assembly 40. The control assembly 40 may dynamically control the horizontal direction (i.e., dynamically manage the horizontal positioning) of the inner diameter r1 of the control ring A during the plasma process of the semiconductor device, enhancing productivity by eliminating process interruptions. The control assembly 40 may uniformly control the distribution of plasma across both the center and edge of the substrate B. The control assembly 40 may linearly and symmetrically adjust the inner diameter r1 of the control ring A with respect to the substrate B along the diameter of the substrate B, allowing precise control of electromagnetic fields and active regulation of plasma on the top surface of the substrate B during the plasma process.

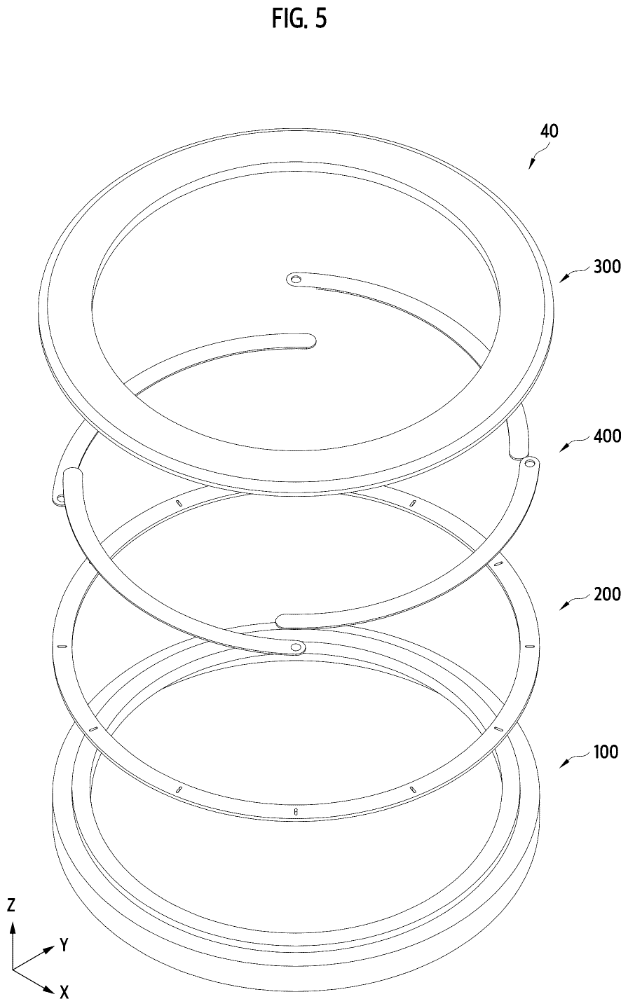

Hereinafter, the control assembly 40 included in the substrate processing apparatus 1 will be described in more detail with reference to FIGS. 5 to 10.

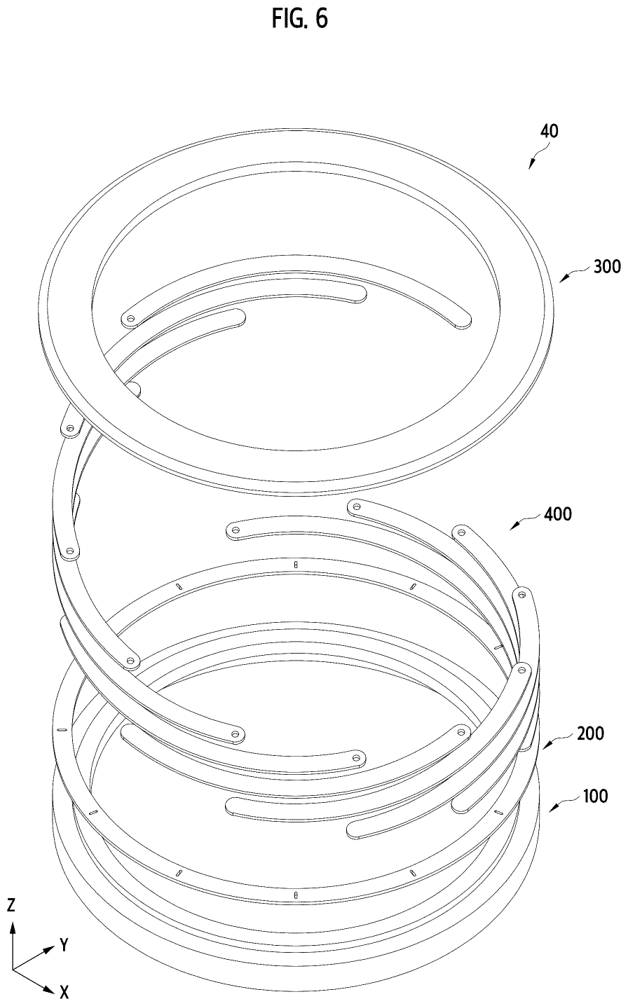

FIGS. 5 and 6 are diagrams of the control assembly 40 included in the substrate processing apparatus 1 according to some example embodiments. Specifically, FIG. 5 simplifies the number of blades to four to clearly illustrate the blade operation of the control assembly 40 according to an example embodiment, and FIG. 6 illustrates a configuration with 12 blades. The number of blades according to some example embodiments is not limited to these figures, and may be freely increased or decreased.

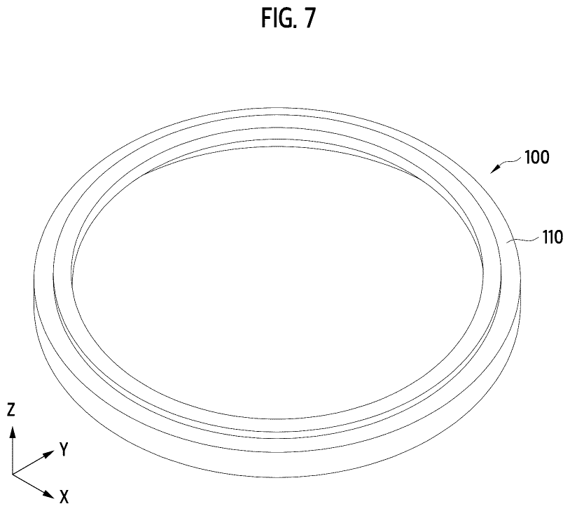

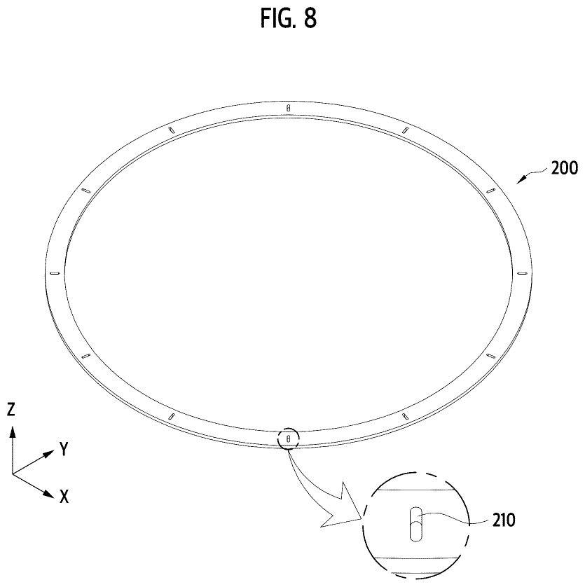

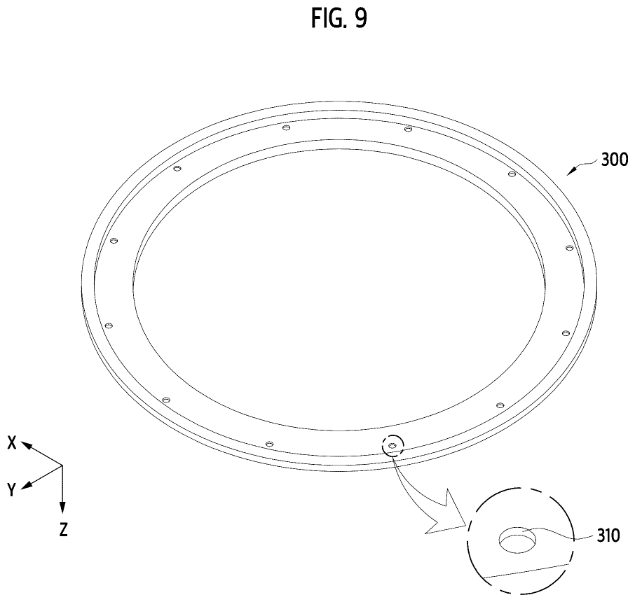

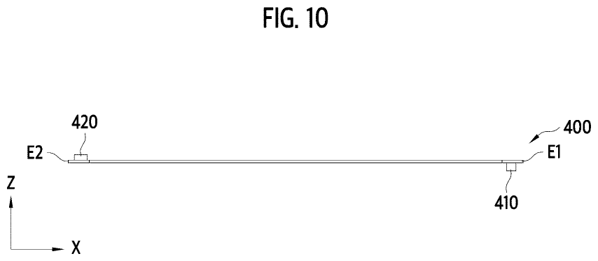

FIG. 7 is a diagram of the base part 100 of the control assembly 40 included in the substrate processing apparatus 1 according to some example embodiments. FIG. 8 is a diagram of a rotation part 200 of the control assembly 40 included in the substrate processing apparatus 1 according to some example embodiments. FIG. 9 is a diagram of a cover part 300 of the control assembly 40 included in the substrate processing apparatus 1 according to some example embodiments. FIG. 10 is a diagram of the blade 400 of the control assembly 40 included in the substrate processing apparatus 1 according to some example embodiments.

Referring to FIGS. 5 to 7, the control assembly 40 may include the base part 100, the rotation part 200, the plurality of blades 400 and the cover part 300.

The base part 100 according to some example embodiments may surround the outer edge of the substrate supporting unit 20 of FIG. 1. The base part 100 may have a ring shape. The base part 100 may be seated on the top surface of the second part 25 of the substrate supporting unit 20, as shown in FIG. 1, and may make contact with the side of the first part 23 of the substrate supporting unit 20, also depicted in FIG. 1. The base part 100 may be dielectric. However, the base part 100 may be formed integrally with the substrate supporting unit 20. For example, the second part 25 of the substrate supporting unit 20 may be integrated with the base part 100.

The base part 100 according to some example embodiments may include a rotation receiving part 110, which is positioned at a distance from the substrate B along the diameter of the substrate B in FIG. 1. The rotation receiving part 110, with a step formed, is designed to accommodate the rotation part 200, which will be described later.

Referring to FIGS. 5, 6 and 8, the rotation part 200 may be placed on the base part 100. The rotation part 200 may have a ring shape. The rotation part 200 may rotate along the circumferential direction of the base part 100. The rotation axis of the rotation part 200 may coincide with the center of the base part 100 depending on the step formed in the rotation receiving part 110. The rotation part 200 may operate the plurality of blades 400. The rotation part 200 may be arranged at a predetermined distance from the substrate B along the diameter of the substrate B in FIG. 1.

The rotation part 200 according to some example embodiments may include a plurality of first connection parts 210 in the form of holes arranged along the circumference of the rotation part 200. The first connection parts 210 may be oval-shaped or slit-shaped holes, with their long axis aligned in the diameter direction of the substrate B. However, the first connection parts 210 may be in the form of grooves rather than holes. The first connection part 210 are not limited to a single point but may be grooves or holes corresponding to a line segment or curve that extends a certain length along a specific angle and direction.

For reference, in the present disclosure, a “hole” may refer to a feature where the material is completely penetrated from one outer surface to the other outer surface. A “groove” may refer to a feature where a step is formed from the outer surface toward the inside.

Referring to FIGS. 5, 6 and 9, the cover part 300 may have a ring shape. The cover part 300 may be arranged to cover the plurality of blades 400. The inner diameter of the cover part 300 is the same as or smaller than the inner diameter r1 of FIG. 4 of the control ring A in FIG. 4. The width of the cover part 300 may be larger than the width of the control ring A formed by the plurality of blades 400. The inner diameter of the cover part 300 may be equal to or larger than the outer diameter of the substrate B in FIG. 3. The cover part 300 may be a dielectric.

The cover part 300 according to some example embodiments may include a plurality of first fixing parts 310 in the form of grooves arranged along the circumferential direction of the cover part 300. The first fixing part 310 may be a groove corresponding to a specific point. When the cover part 300 needs to completely cover the plurality of blades 400 when viewed from the outside, the first fixing part 310 provided in the cover part 300 may be in the form of a groove. The inner surface of the cover part 300 where the first fixing part 310 is provided may be coplanar with the top surface of the substrate B.

Referring to FIGS. 5, 6 and 10, the plurality of blades 400 may be disposed on the rotation part 200. The plurality of blades 400 may be connected to the rotation part 200. For example, the plurality of blades 400 may be fastened to the rotation part 200 in a snap-fit manner. However, the present disclosure is not limited thereto. The method in which the plurality of blades 400 and the rotation part 200 are connected may vary depending on an example embodiment. The plurality of blades 400 may be configured to adjust the plasma distribution area according to the rotation of the rotation part 200. Further, the number of blades may be variable. For example, as illustrated in FIG. 5, there may be four blades, and as illustrated in FIG. 6, there may be 12 blades. As the number of blades 400 increases, the control assembly 40 may linearly control the inner diameter r1 of FIG. 4 of the control ring A of FIG. 4.

The plurality of blades 400 according to some example embodiments may have an arc shape formed along the circumferential direction of the substrate B.

The plurality of blades 400 according to some example embodiments may include a second connection part 410 and a second fixing part 420.

The second connection part 410 according to some example embodiments may protrude toward the rotation part 200. The second connection part 410 may be inserted into the first connection part 210 of FIG. 8. The second connection part 410 may be provided at one end E1 of each of the plurality of blades 400. The second connection part 410 may be in the form of a pin protruding toward the rotation part 200 from the surface where the blades 400 face the rotation part 200.

The second fixing part 420 according to some example embodiments may protrude toward the cover part 300. The second fixing part 420 may be inserted into the first fixing part 310 of FIG. 9. The second fixing part 420 may be provided at an opposite end E2 of each of the plurality of blades 400. The second fixing part 420 may be in the form of a pin that protrudes toward the cover part 300 from the surface of the blades 400 facing the cover part 300.

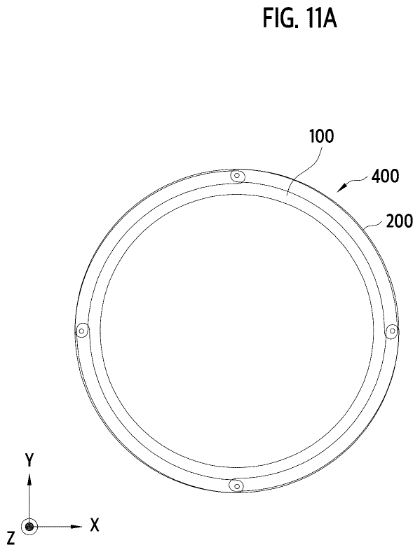

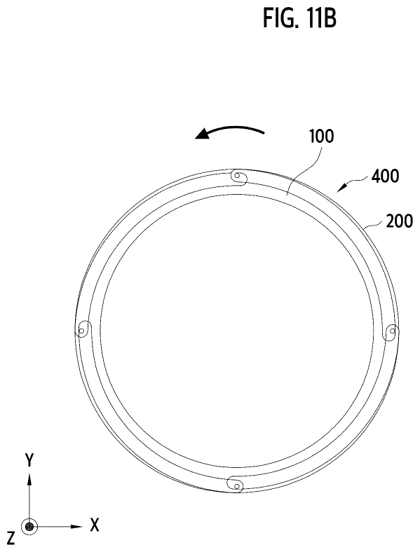

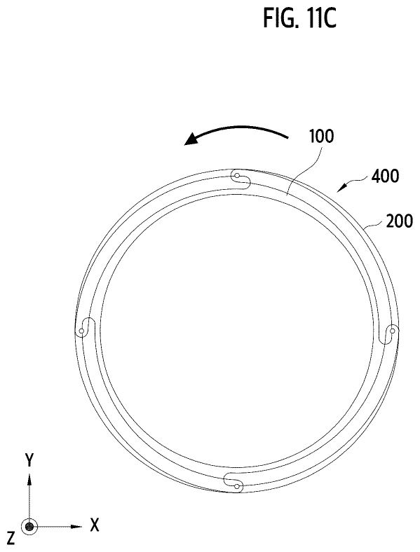

FIGS. 11A-11C schematically show a state in which the blades operate continuously according to the rotation of the rotation part 200. FIGS. 11A-11C schematically illustrate the states in which the blades continuously change according to the rotation of the rotation part 200 when there are four blades.

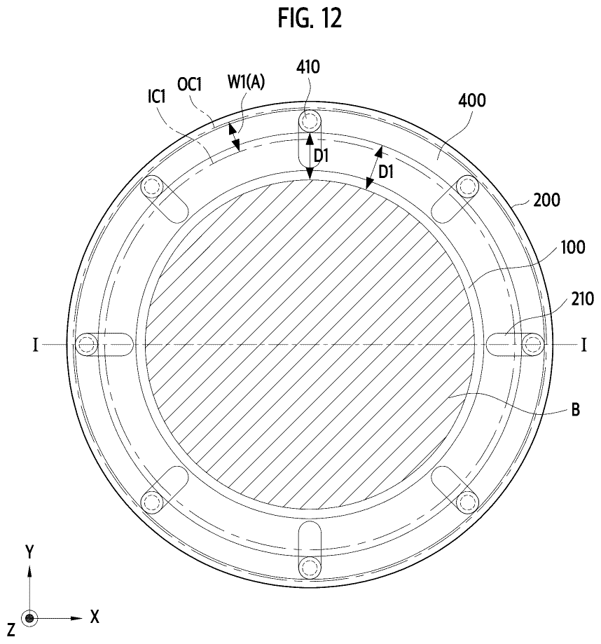

Hereinafter, the mechanical operation method of the control assembly 40 and the detailed structure of each element will be described in more detail referring to FIGS. 12 to 16. FIGS. 12 to 16 have been created to enhance understanding of the mechanical operation methods by exaggerating the sizes of detailed elements of the control assembly 40 according to the present disclosure.

FIGS. 12 to 16 are diagrams showing the movement of the plurality of blades 400 according to the rotation of the rotation part 200 of the control assembly 40 included in the substrate processing apparatus 1.

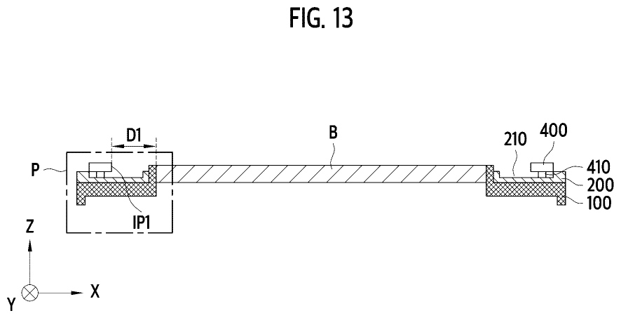

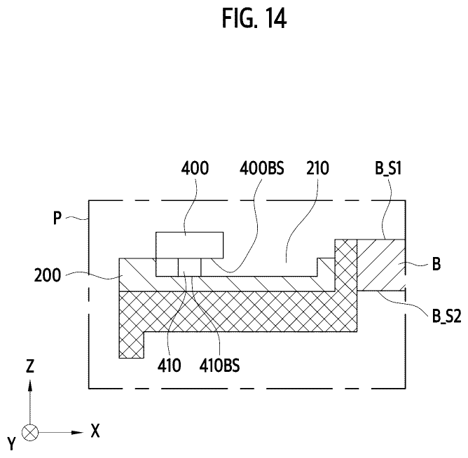

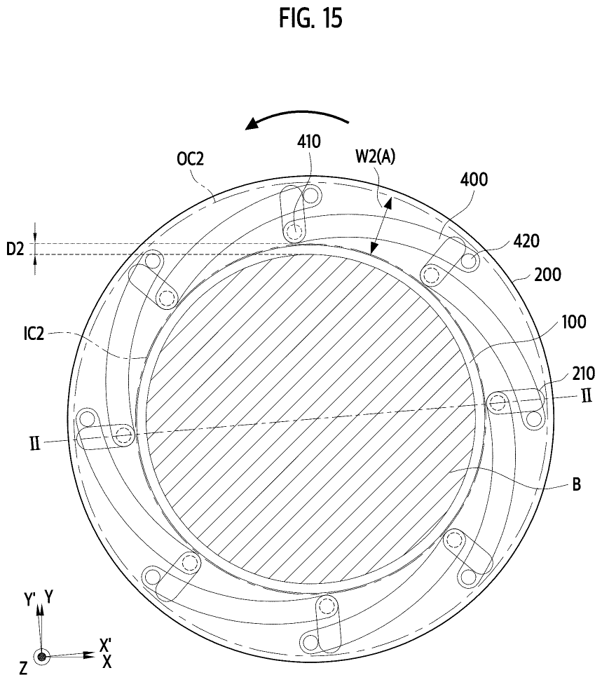

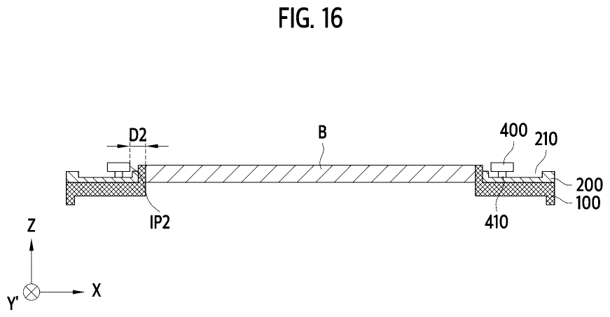

For reference, FIG. 12 is a diagram showing the state before the rotation part 200 rotates. For reference, FIG. 13 illustrates a cross-sectional view taken along line I-I of FIG. 12. For reference, FIG. 14 is an enlarged view showing portion P of FIG. 13. For reference, FIG. 15 is a diagram showing the state after the rotation part 200 rotates. For reference, FIG. 16 shows a cross-sectional view taken along line II-II of FIG. 15.

Referring to FIGS. 12 to 14, the plurality of first connection parts 210 may extend along the diameter direction of the substrate B. For example, the plurality of first connection parts 210 may be radially arranged. The plurality of blades 400 may have an arc shape extending along the circumferential direction of the substrate B. The second connection parts 410 may be inserted into the first connection parts 210.

Before the rotation part 200 rotates some example embodiments, the plurality of blades 400 may be arranged to align with the circumferential direction of the rotation part 200. In other words, the arc shape curvature of the plurality of blades 400 extends in a direction parallel to the curvature of the rotation part's 200 circumference.

The plurality of blades 400 according to some example embodiments may form the control ring A. The outer circumference of the plurality of blades 400 may form virtual first outer circle OC1, and the inner circumference of the plurality of blades 400 may form virtual first inner circle IC1. The area between the virtual first outer circle OC1 and the virtual first inner circle IC1 may be the control ring A.

The virtual first outer circle OC1 according to some example embodiments may be formed by connecting the outermost points of the plurality of blades 400 positioned furthest from the substrate B. The diameter of the virtual first outer circle OC1 may be the outer diameter of the control ring A.

The virtual first inner circle IC1 according to some example embodiments may be formed by connecting first innermost points IP1 of the plurality of blades 400 that are positioned closest to the substrate B. The diameter of the virtual first inner circle IC1 may be the inner diameter of the control ring A. With respect to the diameter direction of the substrate B, the distance between the first innermost points IP1 of the plurality of blades 400 and the substrate B may be first distance D1.

In a state before the rotation part 200 rotates according to some example embodiments, the control ring A may have first width W1. For example, the distance between the first outer circle OC1 and the first inner circle IC1 may be the first width W1. In the state before the rotation part 200 rotates, the second connection parts 410 may be placed outside the first connection parts 210.

The plurality of blades 400 according to some example embodiments may overlap the substrate B in the diameter direction of the substrate B. The plurality of blades 400 may overlap the substrate B in the horizontal direction which is the X-axis direction. Specifically, in the thickness direction of the substrate B, a bottom surface 400BS of the plurality of blades 400 may be disposed between top surface B_S1 of the substrate B and bottom surface B_S2 of the substrate B. However, the present disclosure is not limited thereto.

For example, the bottom surface 400BS of the plurality of blades 400 may be placed above the top surface B_S1 of the substrate B. The distance between the bottom surface 400BS of the plurality of blades 400 and the top surface B_S1 of the substrate B may be 0.3 times of the distance between the plasma generating unit 30 and the top surface B_S1 of the substrate B, or it may shorter. For example, if the distance between the plasma generating unit 30 and the top surface B_S1 of the substrate B is 40 mm, the distance between the bottom surface 400BS of the plurality of blades 400 and the top surface B_S1 of the substrate B may be 12 mm, or it may be shorter. The distance between the bottom surface 400BS of the plurality of blades 400 and the top surface B_S1 of the substrate B may be 0.15 times of the distance between the plasma generating unit 30 and the top surface B_S1 of the substrate B, or it may be shorter. For example, when the distance between the plasma generating unit 30 and the top surface B_S1 of the substrate B is 40 mm, the distance between the bottom surface 400BS of the plurality of blades 400 and the top surface B_S1 of the substrate B may be 6 mm, or may be shorter. Such configurations are designed to prevent the control assembly 40 from being placed too close to the plasma generating unit 30, which could otherwise lead to excessive changes in plasma characteristics or the generation of an arc due to the plasma.

As another example, the bottom surface 400BS of the plurality of blades 400 may be placed below the bottom surface B_S2 of the substrate B. The distance between the bottom surface 400BS of the plurality of blades 400 and the bottom surface B_S2 of the substrate B may be 10 mm, or it may be shorter. This is intended to minimize changes to the hardware structure of the existing chamber when integrating the control assembly 40 into the existing chamber structure.

In the diameter direction of the substrate B, the plurality of blades 400 overlapping the substrate B may control the electromagnetic field distribution for the substrate B by adjusting the distance from the substrate B in the diameter direction of the substrate B.

The second connection part 410 according to some example embodiments may overlap the substrate B in the diameter direction of the substrate B. Bottom surface 410BS of the second connection part 410 may overlap the substrate B in the horizontal direction which is the X-axis direction. In the thickness direction of the substrate B, the bottom surface 410BS of the second connection part 410 may be placed between the top surface B_S1 of the substrate B and the bottom surface B_S2 of the substrate B. However, the present disclosure is not limited thereto.

Referring to FIGS. 15 and 16, when the rotation part 200 is rotated, the plurality of blades 400 may not correspond to the circumferential direction of the rotation part 200. In other words, the arc shaped curvature of the plurality of blades 400 and the curvature of the rotation part's 200 circumference may not be parallel. Instead, they may intersect at a specific angle.

When the rotation part 200 according to some example embodiments rotates, the second connection parts 410 may move within the first connection parts 210. For example, the second connection parts 410 may move from inward from the outer position within the first connection parts 210 relative to the substrate B.

By connecting second innermost points IP2 of the plurality of blades 400 that are positioned closest to the substrate B according to some example embodiments, a virtual second inner circle IC2 may be formed. The diameter of the virtual second inner circle IC2 may be the inner diameter of the control ring A. The diameter of the virtual second inner circle IC2 may be different from the diameter of the virtual first inner circle IC1 in FIG. 10. In other words, depending on the rotation of the rotation part 200, the inner diameter of the control ring A may change.

The minimum value of the inner diameter of the control ring A according to some example embodiments may be the same as the diameter of the substrate B, or it may be greater. Even if the inner diameter of the control ring A changes due to the rotation of the rotation part 200, the inner diameter of the control ring A may be the same as the diameter of the substrate B, or it may exceed the diameter of the substrate B.

The second innermost points IP2 according to some example embodiments may be disposed on the end sides of the plurality of blades 400 where the second connection parts 410 are disposed. In the diameter direction of the substrate B, the distance between the second innermost points IP2 of the plurality of blades 400 and the substrate B may be second distance D2. The second distance D2 may be shorter than the first distance D1 between the substrate B and the first innermost points IP1 of FIG. 13 before the rotation part 200 rotates.

In some example embodiments, a virtual second outer circle OC2 may be formed by connecting the outermost points of the plurality of blades 400 that are positioned furthest from the substrate B. The outermost points of the plurality of blades 400 may be located at the ends of the plurality of blades 400 where the second fixing parts 420 are disposed.

The diameter of the virtual second outer circle OC2 according to some example embodiments may be the outer diameter of the control ring A. The diameter of the second outer circle OC2 may be the same as the diameter of the first outer circle OC1 in FIG. 10. The virtual second outer circle OC2 in which the rotation part 200 rotates along the circumferential direction of the substrate B may be the same as the virtual first outer circle OC1 before the rotation part 200 rotates. In other words, even if the rotation part 200 rotates, the outer diameter of the control ring A may remain constant. This is because, regardless of the rotation of the rotation part 200 along the circumferential direction of the substrate B, the distance between the outermost points of the plurality of blades 400 and the substrate B is constant. Specifically, when the rotation part 200 rotates, the positions of the plurality of first fixing parts 310 in FIG. 8 and the plurality of second fixing parts 420 are fixed.

When the rotation part 200 according to some example embodiments is rotated, the control ring A may have second width W2. For example, the distance between the second outer circle OC2 and the second inner circle IC2 may be the second width W2. The second width W2 may be larger than the first width W1 in FIG. 11 before the rotation part 200 rotates. In other words, according to the rotation of the rotation part 200, the width of the control ring A may change. This is because, when the rotation part 200 rotates along the circumferential direction of the substrate B, the positions of the second fixing parts 420 remain fixed, while the positions of the second connection parts 410 shift closer to the substrate B.

Even if the rotation part 200 according to some example embodiments rotates along the circumferential direction of the substrate B, the positions of the second fixing parts 420 may be fixed without being changed. As the rotation part 200 turns, the plurality of blades 400 may rotate around an axis parallel to the Z axis, defined by the direction in which the second fixing parts 420 protrude. The second fixing parts 420 may rotate in place within the first fixing parts 310, as shown in FIG. 8. As the rotation part 200 rotates, the second connection parts 410 may move within the first connection parts 210.

In other words, as the rotation part 200 according to some example embodiments rotates, the blades 400 fixed to the cover part 300 may rotate around the second fixing parts 420 in FIG. 10, and the range of rotational movement is determined by the shape of the first connection parts 210 in FIG. 8 extending a certain length at a specific angle and direction.

However, elements corresponding to the first connection parts 210 in FIG. 8 may be provided in the cover part 300 according to some example embodiments and the rotation part 200 may be provided with elements corresponding to the first fixing parts 310 in FIG. 9. As such, mechanical movements that are opposite to each other may be performed.

The rotation part 200 according to some example embodiments may be operated by a rotation control apparatus that is connected to the rotation part 200 and generates power necessary for rotation of the rotation part 200. However, a method of controlling the rotation part 200 of the rotation control apparatus may operate not only manually through operator manipulation, but also automatically by electrical signals by connecting to an actuator.

The control assembly 40 according to some example embodiments may control the plasma distribution area by rotating and moving the plurality of blades 400 in the horizontal direction. When the plasma distribution area controlled by the plurality of blades 400 is minimal, the radius corresponding to the area may be larger than the inner diameter of the cover part 300. In other words, in any state of rotational motion, the plurality of blades 400 may be completely covered by the base part 100 and the cover part 300 between the base part 100 and the cover part 300 along the direction of the axis that is parallel to the Z axis.

However, the number of the plurality of blades 400 in some example embodiments is not limited to eight as illustrated in FIGS. 12 to 16. The number of the plurality of blades 400 may vary depending on an example embodiment. When the number of the plurality of blades 400 is changed, the positions and the shapes of the first connecting parts 210 and the first fixing parts 310 may also vary.

The plurality of blades 400 according to some example embodiments may include metal. The plurality of blades 400 according to some example embodiments may be dielectric. The plurality of blades 400 according to some example embodiments may include a magnetic substance. However, material of the plurality of blades is not limited thereto, and the plurality of blades 400 may contain different materials depending on an example embodiment. The density of plasma distribution may vary depending on the material of the plurality of blades 400. Therefore, the material of the blades 400 may be determined based on the linear movement, density and control of plasma distribution during the process.

What is claimed is:

1. An apparatus of processing a substrate, the apparatus comprising:
a substrate supporting unit configured to support the substrate;
a control assembly disposed along an outer edge of the substrate supporting unit, the control assembly including a plurality of blades, wherein the plurality of blades are configured to combine and form a control ring that surrounds the outer edge of the substrate supporting unit; and
a plasma generating unit disposed to face the substrate supporting unit,
wherein the control ring has an inner diameter that is changeable during an operation of the plasma generating unit.

2. The apparatus of claim 1, wherein the control ring has a constant outer diameter.

3. The apparatus of claim 1, wherein the inner diameter of the control ring is equal to or larger than a diameter of the substrate.

4. The apparatus of claim 1, wherein the control assembly includes:
a base part that is ring shaped and surrounds the outer edge of the substrate supporting unit;
a rotation part that is ring shaped, disposed over the based part, rotatable along a circumferential direction of the base part, and configured to operate the plurality of blades; and
a cover part that is ring shaped, disposed to cover the plurality of blades, and has an inner diameter that is equal to or smaller than the inner diameter of the control ring.

5. The apparatus of claim 4, wherein the inner diameter of the control ring changes in response to a rotation of the rotation part.

6. The apparatus of claim 4, wherein the substrate supporting unit includes:
a first part where the substrate is seated; and
a second part that surrounds the first part and supports the base part.

7. The apparatus of claim 6, wherein the second part has a top surface that is at a level lower than a level of a top surface of the first part.

8. The apparatus of claim 4, wherein the base part includes a rotation receiving part that is spaced apart from the substrate along a radial direction of the substrate and includes a step that accommodates the rotation part.

9. The apparatus of claim 4, wherein the rotation part includes a plurality of first connection parts in the form of holes arranged along the circumferential direction, and
wherein the plurality of blades include a plurality of second connection parts that protrude toward the rotation part, and are inserted into the plurality of first connection parts.

10. The apparatus of claim 9, wherein the plurality of first connection parts have an oval shape with a long axis arranged in the radial direction of the substrate.

11. The apparatus of claim 10, wherein the plurality of second connection parts move within the plurality of first connection parts when the rotation part rotates.

12. The apparatus of claim 4, wherein the cover part includes a plurality of first fixing parts in the form of grooves arranged along the circumferential direction, and
wherein the plurality of blades include a plurality of second fixing parts that protrude toward the cover part, and are inserted into the plurality of first fixing parts.

13. The apparatus of claim 12, wherein locations of the plurality of first fixing parts and the plurality of second fixing parts are fixed when the rotation part rotates.

14. The apparatus of claim 13, wherein the plurality of blades rotate around the second fixing parts that are inserted into the first fixing parts when the rotation part rotates.

15. The apparatus of claim 4, wherein the cover part has an inner surface that is coplanar with a top surface of the substrate.

16. The apparatus of claim 1, wherein the plurality of blades are arc-shaped along the circumferential direction of the substrate.

17. An apparatus of processing a substrate, the apparatus comprising:
a substrate supporting unit configured to support the substrate;
a control assembly disposed along an outer edge of the substrate supporting unit, the control assembly including a plurality of blades having an arc-shape extending along a circumferential direction of the substrate, wherein the plurality of blades are configured to form a control ring that surrounds the outer edge of the substrate supporting unit; and
a plasma generating unit disposed to face the substrate supporting unit,
wherein a distance between innermost points of the plurality of blades, closest to the substrate, and the substrate is variable.

18. The apparatus of claim 17, wherein the control assembly further includes:
a base part having a ring shape and surrounding the outer edge of the substrate supporting unit;
a rotation part having a concentric circle shape, disposed over the base part, rotatable along a circumferential direction of the base part, and configured to operate the plurality of blades; and
a cover part having a ring-shape, disposed to cover the plurality of blades, and having an inner diameter that is equal to or smaller than an inner diameter of the control ring,
wherein the rotation part includes a plurality of first connection parts disposed along the circumferential direction, each having an oval shape with a long axis in a direction of a diameter of the substrate,
wherein the cover part includes a plurality of first fixing parts in the form of grooves arranged along the circumferential direction, and
wherein the plurality of blades include:
a plurality of second connection parts disposed at first ends of the plurality of blades, protruding toward the rotation part, and inserted into the plurality of first connection parts; and
a plurality of second fixing parts disposed at second ends opposite to the first ends of the plurality of blades, protruding toward the cover part, and inserted into the plurality of the first fixing parts.

19. The apparatus of claim 17, wherein a distance between a bottom surface of the plurality of blades and a top surface of the substrate is less than or equal to 0.3 times of a distance between the plasma generating unit and the top surface of the substrate.

20. An apparatus of processing a substrate, the apparatus comprising:
a substrate supporting unit configured to support the substrate;
a control assembly disposed along an outer edge of the substrate supporting unit, the control assembly including a plurality of blades having an arc-shape extending along a circumferential direction of the substrate, wherein the blades combined to form a control ring that surrounds the outer edge of the substrate supporting unit; and
a plasma generating unit disposed to face the substrate supporting unit,
wherein the control assembly further includes:
a base part, having a ring shape, that surrounds the outer edge of the substrate supporting unit;
a rotation part, concentric with the base part, disposed over the base part, configured to rotate along a circumferential direction of the base part, and operate the plurality of blades; and
a cover part, having a ring shape, disposed to cover the plurality of blades, and having an inner diameter that is equal to or smaller than an inner diameter of the control ring,
wherein the rotation part includes a plurality of first connection parts disposed along the circumferential direction, each first connection part having an oval shape with its long axis oriented along a direction of a diameter of the substrate,
wherein the cover part includes a plurality of first fixing parts in the form of grooves arranged along the circumferential direction,
wherein each of the plurality of blades include:
a second connection part at one end, protruding toward the rotation part, and inserted into a corresponding first connection part; and
a second fixing part at the opposite end, protruding toward the cover part, and inserted into a corresponding first fixing part,
wherein the inner diameter of the control ring changes with the rotation of the rotation part,
wherein the plurality of second connection parts move within the plurality of first connection parts when the rotation part rotates,
wherein locations of the plurality of first fixing parts and the plurality of second fixing parts are fixed when the rotation part rotates, and
wherein the plurality of blades overlap the substrate in the direction of the diameter of the substrate.
